(19) United States
(12) Patent Application Publication
(10) Pub. No.: US 2025/0111123 A1
(43) Pub. Date: Apr. 3, 2025

(54) STANDARD CELL SPACING QUALITY CHECKING

(71) Applicant: Taiwan Semiconductor Manufacturing Company, Ltd., Hsinchu (TW)

(72) Inventors: Hung-Chih Ou, Kaohsiung City (TW); Yu-Sheng Lu, New Taipei City (TW); Wen-Hao Chen, Hsinchu (TW)

(21) Appl. No.: 18/476,922

(22) Filed: Sep. 28, 2023

(51) Int. Cl. G06F 30/398

(52) U.S. Cl. CPC G06F 30/398

(57) ABSTRACT

A method for checking standard cell spacing in a design includes providing a first standard cell. A cell environment of the first standard cell is determined and a first feasible distance between a first boundary of the standard cell and a boundary of a first adjacent cell based on the cell environment is determined. A second feasible distance between a second boundary of the standard cell and a boundary of a second adjacent cell based on the cell environment is determined. A feasible spacing between the first standard cell and a second standard cell is provided, and the feasible spacing is evaluated based on the first feasible distance, the second feasible distance and a cell pitch of the first standard cell. An integrated circuit is fabricated that includes the first standard cell in response on the evaluating.

### BACKGROUND

Typically, automated tools are employed to assist semiconductor designers in manufacturing a circuit, including taking a functional design of a circuit to a finished layout of the circuit. Integrated circuit (IC) automated design tools are used to transform the circuit design into a circuit layout to be manufactured. This process includes turning a behavioral description of the circuit into a functional description, which is then decomposed into logic functions and mapped into rows of cells using a standard cell library that includes standard cells for predetermined logical functions, such as NAND, NOR, latch, and flip-flop functions. The standard cells may include a transistors, diodes, resistors, inductors, capacitors, or other suitable device, or a combination of one or more such devices formed in a substrate to perform the predetermined logical functions. Automatic place and route (APR) methods and systems may be employed to construct the IC layouts where selected standard cells are placed next to one another in the IC layout. Once mapped into rows of cells, a synthesis is performed to turn the structural design into a physical layout, a clock tree is built to synchronize the structural elements, and the design is optimized post layout. Certain portions of the design and manufacturing process tend to be manual, such as checking quality of the standard cells.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. In addition, the drawings are illustrative as examples of embodiments of the invention and are not intended to be limiting.

FIG. 1 is a block diagram schematically illustrating an example of a processing system, in accordance with some embodiments.

FIG. 2 is a diagram schematically illustrating an example IC design and fabrication process that may include the processing system of FIG. 1, in accordance with some embodiments.

FIG. 3 is a flow diagram illustrating an example of a standard cell spacing quality check process, in accordance with some embodiments.

FIG. 4 is a block diagram illustrating further aspects of the process illustrated in FIG. 3, in accordance with some embodiments.

FIG. 5 is a block diagram illustrating further aspects of the process illustrated in FIG. 3, in accordance with some embodiments.

FIG. 6 is a block diagram illustrating further aspects of the process illustrated in FIG. 3, in accordance with some embodiments.

FIG. 7 is a block diagram illustrating further aspects of the process illustrated in FIG. 3, in accordance with some embodiments.

FIG. 8 is a block diagram illustrating further aspects of the process illustrated in FIG. 3, in accordance with some embodiments.

FIG. 9 is a block diagram illustrating further aspects of the process illustrated in FIG. 3, in accordance with some embodiments.

FIG. 10 is a flow diagram illustrating an example of a standard cell quality check process, in accordance with some embodiments.

FIG. 11 is a block diagram illustrating further aspects of the process illustrated in FIG. 10, in accordance with some embodiments.

FIG. 12 is a block diagram illustrating further aspects of the process illustrated in FIG. 10, in accordance with some embodiments.

FIG. 13 is a block diagram illustrating further aspects of the process illustrated in FIG. 10, in accordance with some embodiments.

FIG. 14 is a flow diagram illustrating an example of a standard cell quality check process, in accordance with some embodiments.

FIG. 15 is a block diagram illustrating further aspects of the process illustrated in FIG. 14, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Automated tools often used to assist semiconductor designers in manufacturing a circuit, including taking a functional design of a circuit to a finished layout of the circuit. The IC design typically includes standard cells or “intellectual property” (IP) blocks (used interchangeably herein), which refer to a reusable, custom designed logic components, storage components, and the like.

In integrated circuit (IC) manufacturing processes, many aspects are automated. However, some portions of the process remain manual, such as checking quality of standard cells during design, optimization, physical implementation, and manufacturing processes for improving power, performance, and area (PPA) of the IC. Such quality checks typically rely on human experience and manual examination of the standard cell. While guidelines for standard cell quality checks may be developed, a systematic approach to checking standard cell quality from the design stage through physical implementation and wafer manufacturing is lacking. Moreover, standard cell quality issues may surface later in the process, such as during physical implementation or wafer manufacturing steps, possibly resulting inferior IC designs quality of return (QoR). For instance, a lack of standard cell design quality review could result in circuits with increased area requirements and/or reduced performance (e.g. slower speed).

The standard cell design process thus relies on human experience for design items such as the cell's size, location, and connections, middle and beginning end of the line (MEOL, BEOL) planning and connections, IO pin accessibility, and the like. Often, standard cell to standard cell spacing is not considered during designing stage. Systematic and well defined checking mechanisms evaluating and comparing the QoR between two cells under a given environment are lacking. Further, while spacing between standard cells can be important in the design process, it can be difficult to model the constraint between two cells for automated processes.

Aspects of this disclosure relate to a standard cell level spacing quality checking methodology. Cell to cell spacing checking is provided for designs under various environments such as power delivery (PG) network structures, pre-placed cell locations, etc. A scoring system is used to represent the cell quality. A cell design flow is used to incorporate the quality checking process, including providing feedback regarding the QoR of the cell so that the cell design quality can ensured prior to release. Further aspects relate to using results of the quality checking process to refine and optimize the standard cell design. Such processes can reduce the cell design turnaround time between design and implementation of cells. Moreover, the standard cell designs can be further optimized for items such as the PPA once the cells have been optimized and pass the validation process.

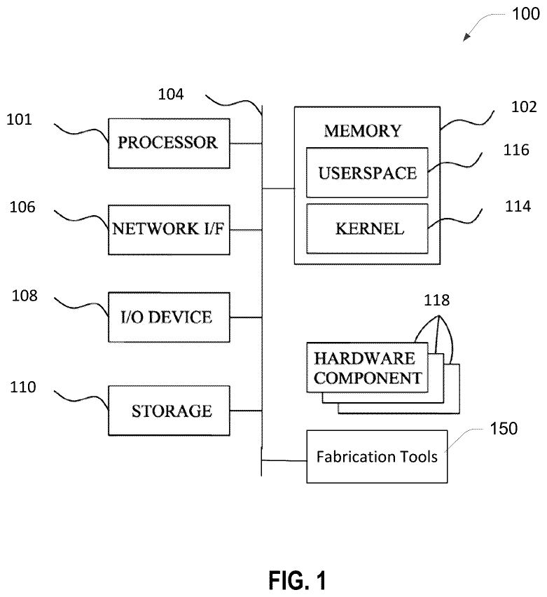

FIG. 1 is a block diagram schematically illustrating an example of a computer system 100, in accordance with some embodiments. In some embodiments, one or more operations and/or functionality of the tools and/or systems described herein are realized by the processor 101, which is programmed for performing such operations and/or functionality. One or more of the memory 102, the I/F 106, the storage 110, the I/O device 108, the hardware components 118, and the bus 104 are operable to receive instructions, data, design rules, netlists, layouts, models and/or other parameters for processing by the processor 101.

In some embodiments, one or more of the operations and/or functionality of the tools and/or systems described herein are implemented by specifically configured hardware (e.g., by one or more application specific integrated circuits or ASIC(s)) which are included) separate from or in lieu of the processor 101. Some embodiments incorporate more than one of the described operations and/or functionality in a single ASIC.

In some embodiments, the operations and/or functionality are realized as functions of a program stored in a non-transitory computer readable recording medium such as the storage 110 and/or memory 102. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, or other suitable non-transitory computer readable recording medium.

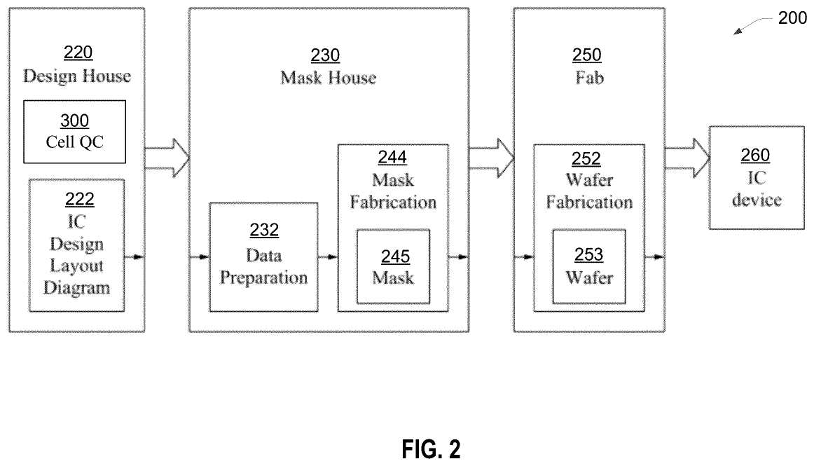

The computer system 100 may further include fabrication tools 150 for implementing the processes and/or methods stored in the storage 110, such as fabricating an IC. For instance, a synthesis may be performed on a design in which the behavior and/or functions desired from the design are transformed to a functionally equivalent logic gate-level circuit description by matching the design to standard cells selected from a layout unit library. The synthesis results in a functionally equivalent logic gate-level circuit description, such as a gate-level netlist. Based on the gate-level netlist, a photolithographic mask may be generated that is used to fabricate the integrated circuit by the fabrication tools 150. Further aspects of device fabrication are disclosed in conjunction with FIG. 2, which is a block diagram of IC manufacturing system 200, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using the manufacturing system 200.

FIG. 2 is a block diagram of IC manufacturing system 200 in accordance with some embodiments. In FIG. 2, the IC manufacturing system 200 includes entities, such as a design house 220, a mask house 230, and an IC manufacturer/fabricator (“fab”) 250, that interact with one another in the design, development, and manufacturing cycles and/or services related to manufacturing an IC device 260. The entities in the system 200 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of the design house 220, mask house 230, and IC fab 250 is owned by a single larger company. In some embodiments, two or more of design house 220, mask house 230, and IC fab 250 coexist in a common facility and use common resources.

The design house (or design team) 220 generates an IC design layout diagram 222. The IC design layout diagram 222 includes various geometrical patterns, or IC layout diagrams designed for an IC device 260. The geometrical patterns correspond to patterns of metal, oxide, or semiconductor layers that make up the various components of IC device 260 to be fabricated. The various layers combine to form various IC features. For example, a portion of the IC design layout diagram 222 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. The design house 220 implements a design procedure to form an IC design layout diagram 222. The design procedure includes one or more of logic design, physical design or place and route. The IC design layout diagram 222 is presented in one or more data files having information of the geometrical patterns. For example, IC design layout diagram 222 can be expressed in a GDSII file format or DFII file format.

The mask house 230 includes a data preparation 232 and a mask fabrication 244. The mask house 230 uses the IC design layout diagram 222 to manufacture one or more masks 245 to be used for fabricating the various layers of the IC device 260 according to the IC design layout diagram 222. The mask house 230 performs mask data preparation 232, where the IC design layout diagram 222 is translated into a representative data file (“RDF”). The mask data preparation 232 provides the RDF to the mask fabrication 244. The mask fabrication 244 includes a mask writer. A mask writer converts the RDF to an image on a substrate, such as a mask (reticle) 245 or a semiconductor wafer 253. The design layout diagram 222 is manipulated by the mask data preparation 232 to comply with particular characteristics of the mask writer and/or requirements of the IC fab 250. In FIG. 2, the mask data preparation 232 and the mask fabrication 244 are illustrated as separate elements. In some embodiments, the mask data preparation 232 and the mask fabrication 244 can be collectively referred to as a mask data preparation.

In some embodiments, the mask data preparation 232 includes an optical proximity correction (OPC) which uses lithography enhancement techniques to compensate for image errors, such as those that can arise from diffraction, interference, other process effects and the like. The OPC adjusts the IC design layout diagram 222. In some embodiments, the mask data preparation 232 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 232 includes a mask rule checker (MRC) that checks the IC design layout diagram 222 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 222 to compensate for limitations during the mask fabrication 244, which may undo part of the modifications performed by OPC in order to meet mask creation rules.

In some embodiments, the mask data preparation 232 includes lithography process checking (LPC) that simulates processing that will be implemented by the IC fab 250 to fabricate the IC device 260. LPC simulates this processing based on the IC design layout diagram 222 to create a simulated manufactured device, such as the IC device 260. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine the IC design layout diagram 222.

It should be understood that the above description of mask data preparation 232 has been simplified for the purposes of clarity. In some embodiments, data preparation 232 includes additional features such as a logic operation (LOP) to modify the IC design layout diagram 222 according to manufacturing rules. Additionally, the processes applied to the IC design layout diagram 222 during data preparation 232 may be executed in a variety of different orders.

After the mask data preparation 232 and during the mask fabrication 244, a mask 245 or a group of masks 245 are fabricated based on the modified IC design layout diagram 222. In some embodiments, the mask fabrication 244 includes performing one or more lithographic exposures based on the IC design layout diagram 222. In some embodiments, an electron-beam (e-beam) or a mechanism of multiple e-beams is used to form a pattern on a mask (photomask or reticle) 245 based on the modified IC design layout diagram 222. The mask 245 can be formed in various technologies. In some embodiments, the mask 245 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of the mask 245 includes a transparent substrate (e.g., fused quartz) and an opaque material (e.g., chromium) coated in the opaque regions of the binary mask. In another example, the mask 245 is formed using a phase shift technology. In a phase shift mask (PSM) version of the mask 245, various features in the pattern formed on the phase shift mask are configured to have proper phase difference to enhance the resolution and imaging quality. In various examples, the phase shift mask can be attenuated PSM or alternating PSM. The mask(s) generated by the mask fabrication 244 is used in a variety of processes. For example, such a mask(s) is used in an ion implantation process to form various doped regions in the semiconductor wafer 253, in an etching process to form various etching regions in the semiconductor wafer 253, and/or in other suitable processes.

The IC fab 250 includes wafer fabrication 252. The IC fab 250 is an IC fabrication business that includes one or more manufacturing facilities for the fabrication of a variety of different IC products. In some embodiments, the IC Fab 250 is a semiconductor foundry. For example, there may be a manufacturing facility for the front end fabrication of a plurality of IC products (FEOL fabrication), while a second manufacturing facility may provide the back end fabrication for the interconnection and packaging of the IC products (BEOL fabrication), and a third manufacturing facility may provide other services for the foundry business.

The IC fab 250 uses mask(s) 245 fabricated by the mask house 230 to fabricate the IC device 260. Thus, the IC fab 250 at least indirectly uses the IC design layout diagram 222 to fabricate the IC device 260. In some embodiments, the semiconductor wafer 253 is fabricated by the IC fab 250 using mask(s) 245 to form the IC device 260. In some embodiments, the IC fabrication includes performing one or more lithographic exposures based at least indirectly on the IC design layout diagram 222. The Semiconductor wafer 253 includes a silicon substrate or other proper substrate having material layers formed thereon. The semiconductor wafer 253 further includes one or more of various doped regions, dielectric features, multilevel interconnects, and the like (formed at subsequent manufacturing steps).

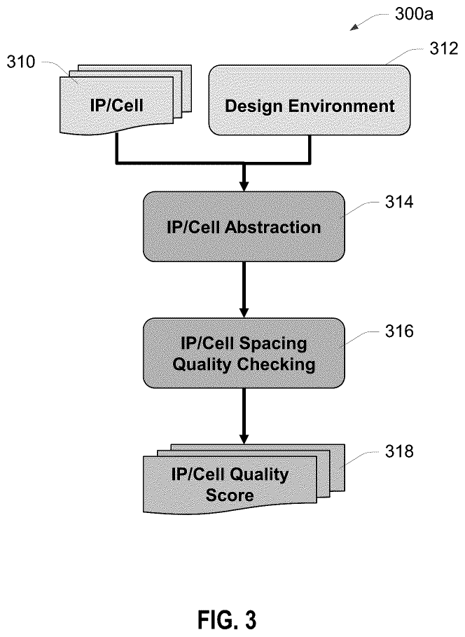

Disclosed embodiments further include an IP or standard cell quality check process 300, which may be implemented by the computer system 100 as part of the design house 220. An example of a first standard cell quality checking process 300a is shown in FIG. 3. The quality checking process 300a is part of a larger design quality check process discussed further below. The process 300a illustrated in FIG. 3 is concerned with, among other things, checking design quality as it relates to cell-to-cell spacing of standard cells in a design. As noted above, the illustrated process 300a may be implemented by the computer system 100 shown in FIG. 1 as part of the design house 220 of FIG. 2.

The process 300a includes providing standard cell designs at operation 310 along with design environments at operation 312, which may include items such as power distribution (i.e. power-ground “PG) networks, pre-placed cells and cell components, and the like. A cell abstraction operation 314 for spacing quality checking uses the provided cells and design environments provided at operations 310 and 312. The cell abstraction provided at operation 314 is then used in a cell spacing quality checking operation 316, where inter-cell spacing is evaluated. The spacing evaluation provided by operation 316 is input to a cell quality scoring operation 318, where a spacing quality score is calculated, which may be compared to a threshold to determine whether the evaluated cell has passed the quality check.

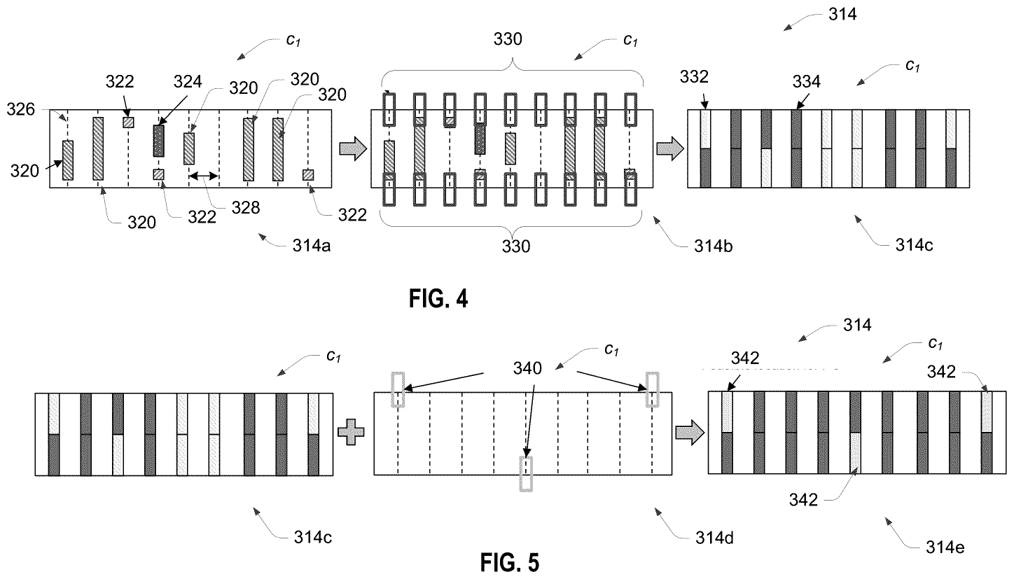

FIG. 4 and FIG. 5 illustrate further aspects of the cell abstraction operation 314, showing various aspects of a standard cell c₁ at different stages of the operation 314. The cell abstraction operation 314 includes modeling physical objects of the cell c₁ at stage 314a. The physical objects could include, for example, shapes 320, electrical interfaces 322 such vias and wires, blockages 324, etc.

The various objects of the cell may be arranged along tracks 326 having a pitch 328 defined as the distance between the tracks 326. In some embodiments, the pitch 328 corresponds to a contact poly pitch (CPP) of an IC process. In some embodiments, pitch 328 corresponds to a metal one pitch of an IC process that is the same as a poly pitch of the IC process. In some embodiments, pitch 328 corresponds to a metal one pitch of an IC process that is different from a poly pitch of the IC process. In some embodiments, pitch 328 corresponds to a multiple of a metal one pitch of an IC process.

At stages 314b and 314c, available locations/solutions are marked on the cell c₁ according to environment constraints such as PG networks, pre-placed cell locations, etc. Thus, at stage 314b, PG locations 330 are identified on the cell c₁, and based on the locations of the physical objects modeled at stage 314a (i.e. shapes 320, electrical interfaces 322, blockages 324) together with the PG locations 330 identified at stage 314b, available locations 332 for the PG network 330 and unavailable locations 334 for the PG network 330 are marked at stage 314c.

FIG. 5 shows the stage 314c from FIG. 4 with the available locations 332 for the PG network 330 and unavailable locations 334 for the PG network 330. PG patterns 340 for the PG network are identified on the cell c₁ at stage 314d, which is combined with the results of stage 314c to derive possible or feasible locations 342 for the PG network as shown in stage 314e.

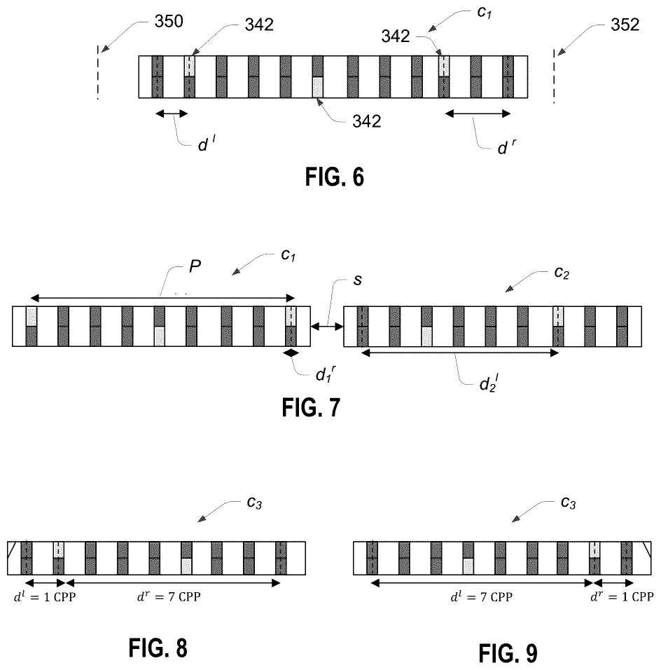

FIGS. 6-8 illustrate further aspects of an example of the cell spacing quality checking operation 316. The operation 316 focuses on evaluating inter-cell spacing (i.e. cell-to-cell spacing), which typically was not addressed in the design process in an objective and automated fashion. The operation 316 thus includes a formula/equation-based spacing quality checking process that begins with transforming the distance of first feasible locations to the left and right boundaries of adjacent cells as variables. Depending on various aspects of the cell c₁, such as the identified feasible locations 342 for the PG network 330, the distance d^{l} to the first feasible location to the left boundary 350 and the distance d^{r} to the first feasible location to the right boundary 352 are determined.

The following equation is used in some embodiments to evaluate the cell-to-cell spacing between cell c₁ and another cell cᵢ:

$$( {d}_{1}^{r} + {d}_{2}^{l} + s + 1 ) mod P = 0 \qquad ( 1 )$$

where s is the feasible spacing between two cells, i.e. the cell c₁ and cell c₂ shown in FIG. 7.
P is the cell pitch, an example of which is identified in FIG. 7 for the cell c₁.
d₁^{r} is the distance from the right boundary of the first cell c₁ to the first feasible location 352 of an adjacent cell to the right of the first cell c₁ (i.e. the cell c₂ shown in FIG. 7).
d₂^{l} is the distance from the left boundary of the second cell c₂ to the first feasible location 350 of the adjacent cell to the left of the second cell c₂ (i.e. the first cell c₁).

In some embodiments, inputs to equation (1) (and other equations disclosed below) are input into a computer memory such as the storage 110 and/or memory 102 of the system 100 illustrated in FIG. 1. Such inputs could be provided by a user using the I/O device 108, or received via the network interface 106. Some of the inputs may be calculated by the processor 101 and stored in the appropriate memory.

If equation (1) is true, s is the feasible cell-to-cell spacing between the cells c₁ and c₂. The closer the result of equation (1) is to 0, the better the design quality with regard to cell-to-cell spacing. Moreover, this cell spacing quality check process 300a can be used as part of a larger scale quality check process for checking a design including a plurality of standard cells.

It should be noted that d^{l} and d^{r} will change depending on the orientation of the cell. FIG. 8 shows a cell c₃ in which d^{l} and d^{r} are 1CPP and 7CPP, respectively. FIG. 9 shows a reverse orientation of the cell c₃ (i.e. mirror image), such that d^{l} and d^{r} are opposite. With the cell c₃ oriented as shown in FIG. 9, d^{l} and d^{r} are 7CPP and 1CPP, respectively.

At operation 318 of FIG. 3, the cell level spacing quality operation 316 is used to determine a cell quality score. In some embodiments, the feasible spacings between a given cell (e.g. cell c₁) and other cells in an IC design are calculated to determine a spacing quality score for the given cell.

For instance, a standard cell spacing score g for the first cell c₁ as it relates to another cell cᵢ can be determined according to equation (2):

$${g}_{i} = \frac{\# of feasible spacing between {C}_{1} and {C}_{i}}{2 \cdot P} \qquad ( 2 )$$

The feasible spacing number determined by equation (1) is thus used in equation (2) to determine a spacing quality score for spacing between the first cell c₁ and another cell cᵢ.

An overall spacing quality score S can then be determined for the cell c₁ as it relates to all of the other cells cᵢ in the design according to equation (3).

$$S = \frac{{\sum }_{i = 1}^{n} {g}_{i}}{n} \qquad ( 3 )$$

In equation (3), the spacing quality scores gᵢ for the cell c₁ to n other cells cᵢ is summed and divided by the number n of other cells cᵢ. The overall score S for a particular design, which represents the cell-to-cell spacing quality score for the standard cells of a design, may then compared to a threshold T to determine a quality check pass/fail.

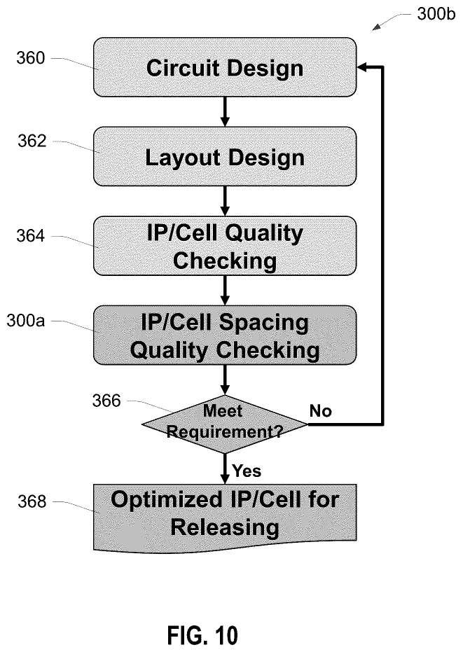

FIG. 10 is a flow diagram illustrating another process 300b associated with the standard cell quality check process 300 shown in FIG. 2. The process 300b shown in FIG. 10 incorporates the standard cell spacing quality check process 300a shown in FIG. 3 into the standard cell design process. In the process 300b of FIG. 10, each designed standard cell is checked with the design specific environment constraints before release. Thus, at operation 360 a standard cell circuit design is provided, and at operation 362 a layout design for the cell is provided. The cell circuit design 360 and layout design 362 operations may be associated with the design house 220 disclosed in conjunction with FIG. 2 as part of the IC design. At operation 364 a standard cell quality checking process may be conducted in which various quality checks on the circuit and layout provided in operations 360 and 362. The quality checking process of operation 364 may check functional items such as cell operation efficiency and accuracy, cell area utilization, and compliance with various design rules.

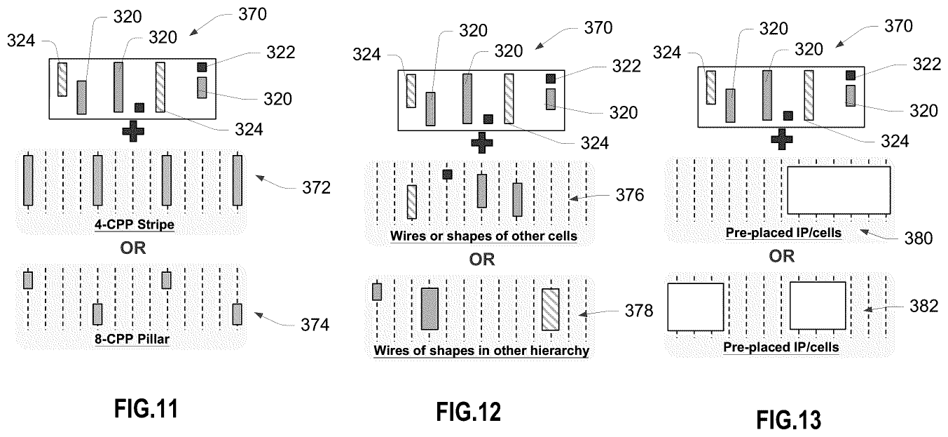

In the process 300b of FIG. 10, the cell spacing quality check process 300a of FIG. 3 is conducted to assess cell-to-cell spacing of cells in the design provided at operations 360 and 362. Each of the standard cell designs provided in operations 360 and 362 are checked with a design specific environment constraints before release. As noted above in conjunction with the process 300a, design environments were provided at operation 312 of the process 300a shown in FIG. 3. As shown in FIG. 11, the design environments for a standard cell design 370 include, for example, shapes 320, electrical interfaces 322 such vias and wires, blockages 324, etc. Different types and styles of PG network components are considered, including stripe 372 or pillar 374, together with various spacing and pitches for the different PG components (e.g., 8-CPP or 4-CPP for VDD to VDD spacing).

In FIG. 12, different locations such as design boundary or hierarchy for the cell design is considered for items such as the wires and other electrical interfaces 322, shapes 320, etc. are considered relative to the components of other cells 376 or other hierarchies 378. FIG. 13 illustrates an example where various pre-placed cells are evaluated for the cell design 370. For instance, various pre-placed abutment scenarios or orientation may be considered. In FIG. 13, two different pre-placed cell sizes and shapes may be considered at 380 and 382.

These design specific environment constraints may be used in the standard cell level spacing quality check process 300a to determine feasible boundary locations for input to equations (1) and (2) disclosed above. If results of the cell spacing quality check process 300a meet a predetermined threshold in operation 366, the cell is released for use in the design. If the threshold is not met in operation 366, the process repeats and the design may be revised and optimized for cell-to-cell spacing. The design with the optimized cell(s) may then be released in operation 368 for IC manufacturing, such as by the fab 250 shown in FIG. 2, which may employ the fabrication tools 150 and other components of the system 100 shown in FIG. 1.

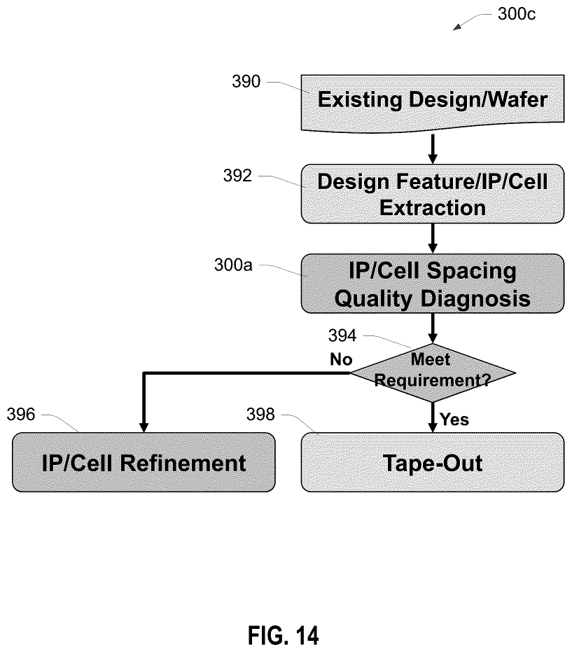

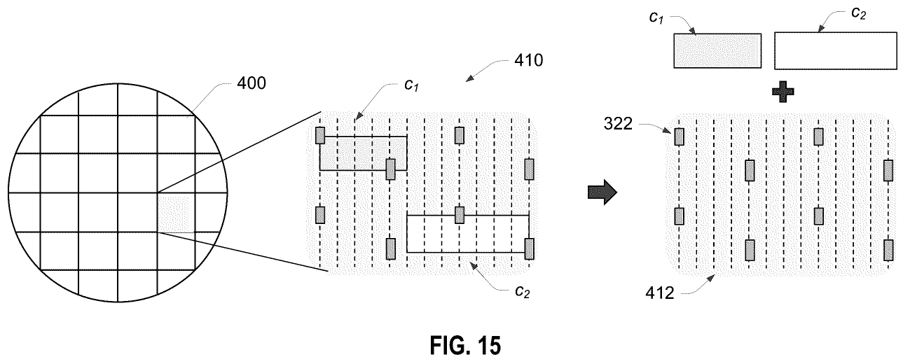

In accordance with further aspects, an existing design may be evaluated for cell-to-cell spacing quality to diagnose and improve quality issues for the existing designs. FIG. 14 illustrates such a process 300c, which incorporates the cell spacing quality check 300a. At operation 390 and existing design or wafer is provided. For instance, as shown in FIG. 15, an existing design 410 of a wafer 400 may be analyzed using the cell spacing quality checking process 300a to identify and diagnose quality issues with the design 410. In some embodiments, a defective or under-performing existing standard cell design may be extracted for the purposes of refining and improving the design.

At operation 392, environment constraints are extracted from the design 410. In FIG. 15, environmental constraints 412 such as electrical interfaces 322 associated with two standard cells c₁ and c₂ included in the design 410 are extracted. These environmental constraints can be used to determine feasible cell spacings for the cells c₁ and c₂, and this information can be input to the equations (1)-(3) to evaluate cell spacing quality. If the results of the cell spacing quality check process 300a meet predetermined thresholds at operation 394, the existing design is released for fabrication of an IC, such as by the fab 250 shown in FIG. 2, which may employ the fabrication tools 150 and other components of the system 100 shown in FIG. 1. If quality requirements are not met at operation 394, the standard cell design(s) evaluated are refined at operation 396.

Disclosed embodiments thus disclose processes and systems for checking and evaluating the spacing quality between standard cells based on a design environment. Moreover, such cell-to-cell spacing quality checking may be formed in an objective and automated fashion, using disclosed process flows for standard cell level design checking to insure cell design quality before releasing the design, as well as process flows for cell spacing quality for existing designs or wafers. This facilitates further improvements for factors such PPA for existing designs. This may reduce standard cell design turnaround time and further boost performance (e.g. PPA) by insuring all standard cell designs meet intercell spacing criteria.

In accordance with some disclosed aspects, a method for checking standard cell spacing in a design includes providing a first standard cell. A cell environment of the first standard cell is determined and a first feasible distance between a first boundary of the standard cell and a boundary of a first adjacent cell based on the cell environment is determined. A second feasible distance between a second boundary of the standard cell and a boundary of a second adjacent cell based on the cell environment is determined. A feasible spacing between the first standard cell and a second standard cell is provided, and the feasible spacing is evaluated based on the first feasible distance, the second feasible distance and a cell pitch of the first standard cell. An integrated circuit is fabricated that includes the first standard cell in response on the evaluating.

In accordance with further disclosed aspects, a method for checking standard cell spacing in a design includes providing a first standard cell and providing a plurality of additional standard cells. A plurality of feasible spacings between the first standard cell and the respective plurality of additional standard cells are evaluated, which includes determining a plurality of spacing scores for each of the plurality of feasible spacings and determining an overall spacing score based on the plurality of spacing scores. An integrated circuit is fabricated in response to the overall spacing score.

In accordance with additional disclosed aspects, a system includes a processor and a memory storage accessible by the processor that storing instructions that when executed by the processor perform a method that includes evaluating a feasible spacing between a first standard cell and a second standard cell. The feasible spacing is based on a first feasible distance between a first boundary of the standard cell and a boundary of a first adjacent cell, a second feasible distance between a second boundary of the standard cell and a boundary of a second adjacent cell, and a cell pitch of the first standard cell.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
providing a first standard cell;
determining a cell environment of the first standard cell;
determining a first feasible distance between a first boundary of the first standard cell and a boundary of a first adjacent cell based on the cell environment;
determining a second feasible distance between a second boundary of the first standard cell and a boundary of a second adjacent cell based on the cell environment;
providing a feasible spacing between the first standard cell and a second standard cell;
evaluating the feasible spacing based on the first feasible distance, the second feasible distance and a cell pitch of the first standard cell; and
fabricating an integrated circuit that includes the first standard cell in response on the evaluating.

2. The method of claim 1, further comprising modifying a design of the first standard cell based on the evaluating.

3. The method of claim 2, further comprising determining a standard cell spacing score for the first standard cell based on the evaluating.

4. The method of claim 3, wherein the fabricating the integrated circuit is conducted if the standard cell spacing score exceeds a threshold.

5. The method of claim 1, further comprising modeling a plurality of physical objects of the first standard cell, wherein determining the first feasible distance and the second feasible distance are further based on the modeling.

6. The method of claim 5, wherein the plurality of physical objects includes at least one of shapes, electrical interfaces, vias, wires, and/or blockages.

7. The method of claim 1, wherein the cell environment includes at least one of power networks and/or pre-placed cell locations.

8. The method of claim 1, wherein the feasible spacing is evaluated based on the following equation
$$( {d}_{1}^{r} + {d}_{2}^{l} + s + 1 ) mod P = 0$$
where
s is the feasible spacing between the first standard cell and the second standard cell;
P is the cell pitch;
d₁^{r} is the first feasible distance; and
d₂^{l} is the second feasible distance.

9. The method of claim 8, further comprising:
providing a plurality of feasible spacings between the first standard cell and a respective plurality of additional standard cells;
evaluating the plurality of feasible spacings; and
fabricating the integrated circuit that includes the first standard cell and the plurality of additional standard cells based on the evaluating the plurality of feasible spacings.

10. The method of claim 1, further comprising:
providing a circuit design;
providing a layout design; and
wherein the cell environment is based on the circuit design and the layout design.

11. The method of claim 1, further comprising:
providing an existing wafer including the first standard cell;
wherein the cell environment is extracted from the existing wafer.

12. A method, comprising:
providing a first standard cell;
providing a plurality of additional standard cells;
evaluating a plurality of feasible spacings between the first standard cell and the respective plurality of additional standard cells, including:
determining a plurality of spacing scores for each of the plurality of feasible spacings;
determining an overall spacing score based on the plurality of spacing scores; and
fabricating an integrated circuit in response to the overall spacing score.

13. The method of claim 12, wherein evaluating the plurality of feasible spacings includes:
determining a cell environment of the first standard cell;
determining a first feasible distance between a first boundary of the first standard cell and a boundary of a first adjacent cell based on the cell environment; and
determining a second feasible distance between a second boundary of the first standard cell and a boundary of a second adjacent cell based on the cell environment.

14. The method of claim 13, wherein the plurality of feasible spacings are evaluated based on the first feasible distance, the second feasible distance and a cell pitch of the first standard cell.

15. The method of claim 12, further comprising modifying a design of the first standard cell based on the evaluating.

16. The method of claim 12, wherein a design of the first standard cell is refined if the overall spacing score is below a threshold.

17. A system, comprising:
a processor;
a memory storage accessible by the processor and storing instructions that when executed by the processor perform a method comprising evaluating a feasible spacing between a first standard cell and a second standard cell;
wherein the feasible spacing is based on a first feasible distance between a first boundary of the first standard cell and a boundary of a first adjacent cell, a second feasible distance between a second boundary of the first standard cell and a boundary of a second adjacent cell, and a cell pitch of the first standard cell.

18. The system of claim 17, wherein the executed method further comprises:
receiving a cell environment of the first standard cell, and
determining the first feasible distance and the second feasible distance based on the cell environment.

19. The system of claim 18, wherein evaluating the feasible spacing includes calculating a standard cell spacing score for the first standard cell.

20. The system of claim 19, wherein the executed method further comprises:
evaluating a plurality of feasible spacings between the first standard cell and a respective plurality of additional standard cells;
calculating a plurality of the standard cell spacing scores for each of the respective evaluated plurality of feasible spacings;
calculating an overall spacing score based on the plurality of spacing scores; and
comparing the overall spacing score to a threshold.
